(19) United States
(12) Patent Application Publication
(10) Pub. No.: US 2025/0221320 A1
(43) Pub. Date: Jul. 3, 2025

(54) POWER MODULES

(71) Applicants: Hyundai Motor Company, Seoul (KR); Kia Corporation, Seoul (KR)

(72) Inventors: SUK HYUN LIM, Hwaseong-Si (KR); Han Jin DO, Incheon (KR)

(73) Assignees: Hyundai Motor Company, Seoul (KR); Kia Corporation, Seoul (KR)

(21) Appl. No.: 19/085,109

(22) Filed: Mar. 20, 2025

Related U.S. Application Data
(63) Continuation of application No. 18/806,338, filed on Aug. 15, 2024.

(30) Foreign Application Priority Data
Nov. 21, 2023 (KR) 10-2023-0162482

(51) Int. Cl. H10N 59/00; H01L 23/00; H01L 23/46; H01L 23/49; H01L 23/538; H01L 25/16

(52) U.S. Cl. CPC H10N 59/00; H01L 23/49; H01L 23/5385; H01L 24/48; H01L 25/16; H01L 23/46; H01L 24/32; H01L 24/73; H01L 2224/32225; H01L 2224/48175; H01L 2224/73265

(57) ABSTRACT

A power module includes a first substrate including a sensing target portion in which a current path is formed in a first direction, a second substrate spaced from the first substrate in a second direction crossing the first substrate, and a Hall element disposed between the first substrate and the second substrate to face the sensing target portion with an interval with the sensing target portion, and electrically connected to the outside of the power module, and configured to generate voltage according to a magnetic field occurring due to a current flowing in the sensing target portion.

### CROSS REFERENCE TO RELATED APPLICATIONS

The present application claims priority to Korean Patent Application No. 10-2023-0162482, filed Nov. 21, 2023, the entire contents of which is incorporated herein for all purposes by this reference.

### BACKGROUND OF THE PRESENT DISCLOSURE

### Field of the Present Disclosure

The present disclosure relates to a power module configured for detecting current through a Hall element provided therein.

### Description of Related Art

In recent, as interest in the environment has increased, the number of eco-friendly vehicles equipped with electric motors as a power source is increasing. The eco-friendly vehicles are also called electrified vehicles, and representative examples thereof include electric vehicles (EV) and hybrid electric vehicles (HEV).

The electric vehicle is equipped with an inverter for converting DC power into AC power when driving a motor, and the inverter is usually made of one or a plurality of power modules equipped with a semiconductor chip performing switching function.

To control a power conversion system of a vehicle equipped with a power module, current of the power module needs to be detected. To the present end, a current sensor may be provided outside the power module, or a resistor such as a shunt resistor may be provided inside the power module.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing power module, which is configured to detect current using a Hall element provided therein to reduce a volume and cost for performing current sensing and to improve the accuracy of the current sensing.

The problem of the present disclosure is not limited to the above mention, and other problems not mentioned will be clearly understood by those skilled in the art from the description below.

To achieve the above-mentioned problem, according to an exemplary embodiment of the present disclosure, there is provided a power module including: a first substrate including a sensing target portion in which a current path is formed in a first direction thereof, a second substrate spaced from the first substrate in a second direction crossing the first substrate; and a Hall element disposed between the first substrate and the second substrate to face the sensing target portion with an interval with the sensing target portion, and electrically connected to the outside of the power module, and configured to generate voltage according to a magnetic field occurring due to a current flowing in the sensing target portion.

For example, the second substrate may include: a first portion electrically separated from the first substrate, and the Hall element may be electrically connected to the first portion so that current is applied thereto.

For example, the power module according to the exemplary embodiment of the present disclosure may include: a semiconductor chip electrically connected to the first substrate.

For example, the power module according to the exemplary embodiment of the present disclosure may include: a signal pin electrically connecting the Hall element to the outside of the power module.

For example, the voltage generated in the Hall element may be applied to the signal pin.

For example, the Hall element may be electrically connected to the signal pin by at least one selected from a group consisting of wire bonding connection and bonding with the signal pin.

For example, the first portion may be electrically connected to the outside of the power module, and the Hall element may be electrically connected to the outside of the power module through the first portion.

For example, the power module according to the exemplary embodiment of the present disclosure may include a signal pin connected to the first portion and electrically connecting the Hall element to the outside of the power module, wherein the first portion may be electrically connected to the signal pin by at least one selected from a group consisting of wire bonding connection and bonding with the signal pin.

For example, the Hall element may be electrically connected to the first portion while being bonded to the first portion in a form of a bare die.

For example, the Hall element may be electrically connected to the first portion through a connector.

For example, the Hall element may be electrically connected to the connector by wire bonding.

For example, an insulating layer may be inserted between the Hall element and the connector.

For example, the first portion may be divided into a plurality of portions in a third direction, the third direction crossing the first direction and the second direction, and the connector may include a first connector and a second connector, the first connector and the second connector being separated from each other and respectively connected to a corresponding one among the plurality of portions of the first portion.

For example, the connector may be electrically connected to the outside of the power module, and the Hall element may be electrically connected to the outside of the power module through the connector.

For example, the power module may include a semiconductor chip electrically connected to the first substrate, wherein the second substrate may further include: a second portion electrically separated from the first portion, and electrically connected to the semiconductor chip.

For example, the first portion and the second portion may be spaced from each other in a third direction, the third direction crossing the first direction and the second direction thereof.

For example, an insulating body may be inserted in a gap between the first portion and the second portion.

For example, a cooling channel may be connected to at least one selected from a group consisting of the first substrate and the second substrate.

According to the various embodiments of the present disclosure described above, current sensing is performed through the Hall element provided in the power module, so that the influence due to changes in temperature and magnetic field in the current sensing process may be reduced.

Furthermore, it is possible to reduce the size and cost of the current sensor, and moreover, it is possible to reduce the size and cost of the power module, in which the current sensor is embedded, and an inverter.

The effect of the present disclosure is not limited to the above mention, and other effects not mentioned will be clearly understood by those skilled in the art from the description below.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1, FIG. 2, FIG. 3, FIG. 4, and FIG. 5 are views showing structures of a power module according to various exemplary embodiments of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

In the following description, the structural or functional description specified to an exemplary embodiment according to the concept of the present disclosure is directed to describe the exemplary embodiments of the present disclosure, so it should be understood that the present disclosure may be variously embodied, without being limited to the exemplary embodiments of the present disclosure.

Embodiments described herein may be changed in various ways and various shapes, so specific embodiments are shown in the drawings and will be described in detail in the present specification. However, it should be understood that the exemplary embodiments according to the concept of the present disclosure are not limited to the exemplary embodiments which will be described hereinbelow with reference to the accompanying drawings, but all of modifications, equivalents, and substitutions are included in the scope and spirit of the present disclosure.

Unless otherwise defined, all terms including technical and scientific terms used herein have the same meaning as commonly understood by those skilled in the art to which the present disclosure belongs. It may be understood that the terms defined by the dictionary are identical with the meanings within the context of the related art, and they should not be ideally or excessively formally defined unless the context clearly dictates otherwise.

Hereafter, an exemplary embodiment of the present disclosure will be described in detail with reference to the accompanying drawings and the same or similar components are provided the same reference numerals regardless of the numbers of figures and are not repeatedly described.

In the description of the following embodiments, the term “preset” means that when a parameter is used in a process or algorithm, a value of the parameter is predetermined. A value of the parameter may be preset when the process or algorithm starts depending on an exemplary embodiment of the present disclosure, or may be preset during a section when the process or algorithm is performed.

The suffixes “module” and “part” for the components used in the following description are provided or mixed in consideration of only the ease of writing the specification, and do not have distinct meanings or roles by themselves.

In the following description, if it is decided that the detailed description of known technologies related to the present disclosure makes the subject matter of the exemplary embodiment described herein unclear, the detailed description is omitted. Furthermore, the accompanying drawings are provided only for easy understanding of the exemplary embodiment disclosed in the specification, and the technical spirit disclosed in the specification is not limited by the accompanying drawings, and all changes, equivalents, and replacements should be understood as being included in the spirit and scope of the present disclosure.

Terms including ordinal numbers, such as “first”, “second”, etc., may be used to describe various components, but the components are not to be construed as being limited to the terms. The terms are used only to distinguish one component from another component.

It is to be understood that when one element is referred to as being “connected to” or “coupled to” another element, it may be directly connected to or directly coupled to another element or be connected to or coupled to another element, having the other element intervening therebetween. On the other hand, it should be understood that when one element is referred to as being “directly connected to” or “directly coupled to” another element, it may be connected to or coupled to another element without the other element intervening therebetween.

Singular forms are intended to include plural forms unless the context clearly indicates otherwise.

It will be further understood that the terms “comprise” or “have” used in the present specification, specify the presence of stated features, steps, operations, components, parts, or a combination thereof, but do not preclude the presence or addition of one or more other features, numerals, steps, operations, components, parts, or a combination thereof.

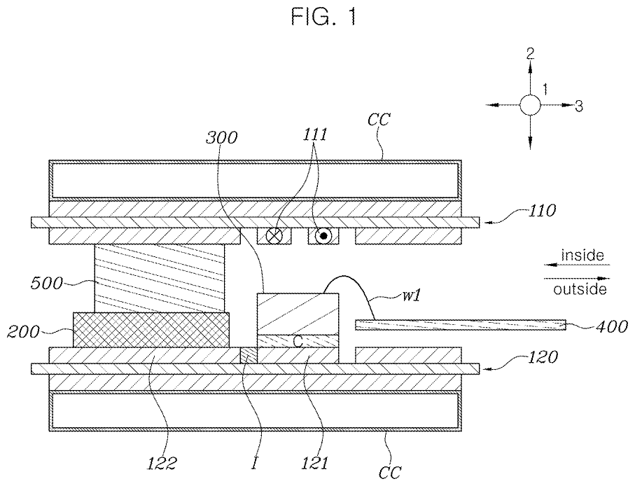

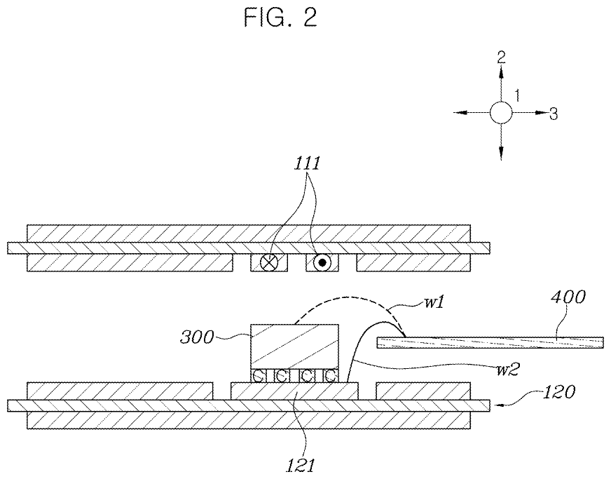

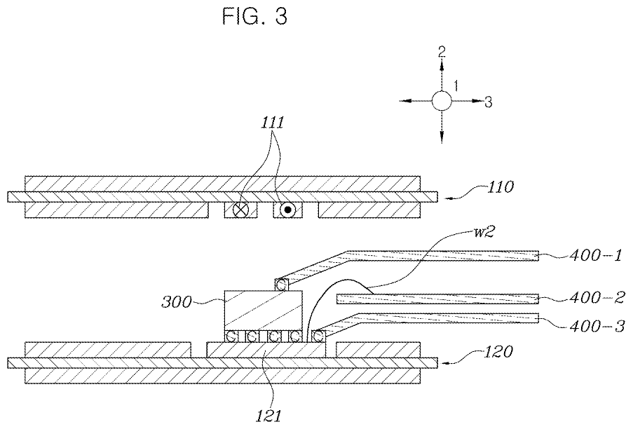

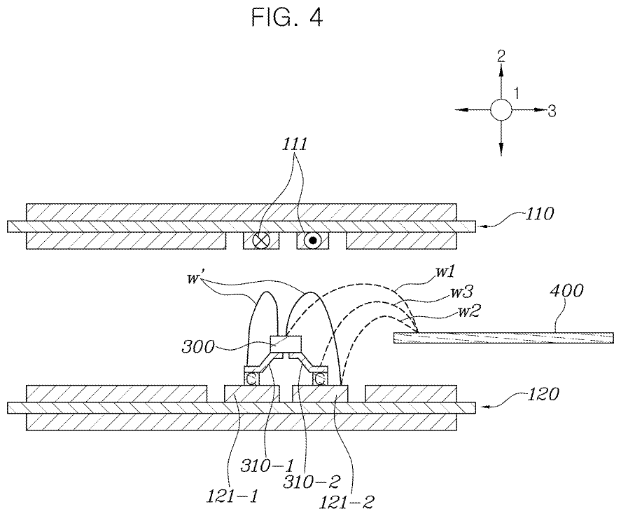

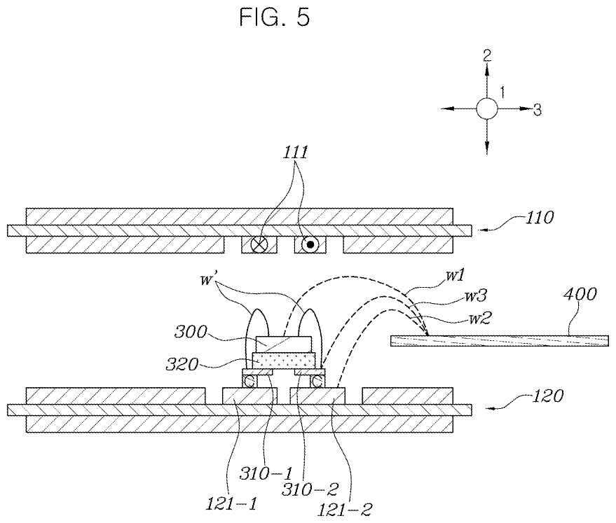

Hereinbelow, a power module according to various exemplary embodiments of the present disclosure will be described with reference to FIG. 1, FIG. 2, FIG. 3, FIG. 4, and FIG. 5.

FIG. 1, FIG. 2, FIG. 3, FIG. 4, and FIG. 5 are views showing structures of a power module according to various exemplary embodiments of the present disclosure.

Referring to FIG. 1, FIG. 2, FIG. 3, FIG. 4, and FIG. 5, according to the exemplary embodiments of the present disclosure, the power module may include a first substrate 110, a second substrate 120, a semiconductor chip 200, a Hall element 300, a signal pin 400, and a spacer 500. However, FIG. 1 mainly shows components, which relate to the description for the exemplary embodiments of the present disclosure, and the power module may be actually implemented with components more or less than the shown components. Hereinbelow, according to the exemplary embodiments the present disclosure, each configuration of the power module will be described.

First, the first substrate 110 includes a sensing target portion 111 in which a current path is formed in a first direction thereof. The first substrate 110 may be electrically connected to the semiconductor chip 200. In the instant case, current applied from the outside of the power module is transmitted to the first substrate 110 through the semiconductor chip 200 and the transmitted current flows along the current path formed in the sensing target portion 111.

The current path formed in the sensing target portion 111 is spaced from another current path in parallel to each other on one cross section as shown in FIG. 1, FIG. 2, FIG. 3, FIG. 4, and FIG. 5, and may include portions with different current directions, and may be formed in various forms such as including portions facing in the same direction on one cross section, unlike the shown form in FIG. 1, FIG. 2, FIG. 3, FIG. 4, and FIG. 5.

The sensing target portion 111 may be realized in an insulation pattern on a surface of the first substrate, and in response to a form of the insulation pattern, the current path may be determined.

The second substrate 120 is disposed in a second direction that crosses the first direction 110 to be spaced from the first substrate. The second substrate 120 may include a first portion 121 electrically separated from the first substrate 110, and the first portion 121 may be electrically connected to the Hall element 300.

Meanwhile, the above-described first substrate 110 and second substrate 120 may include insulating layers and metal layers, respectively, and the first substrate 110 and the second substrate 120 may be disposed to be vertically spaced from each other so that the respective metal layers are opposite to each other.

Each of the insulating layers may be configured to achieve electrical cut-off between the inside and outside of the power module, and each of the metal layers may be configured to achieve current flow in the internal portion of the power module.

In the instant case, the sensing target portion 111 and the first portion 121 may be a portion of the metal layer of the first substrate 110 and a portion of the metal layer of the second substrate 120, respectively.

Furthermore, to improve cooling efficiency, the insulating layer may include an additional metal layer which is disposed to face the outside of the power module in addition to the metal layer disposed on a surface facing the internal portion of the power module. The additional metal layer may serve to cool the power module by discharge heat outwards, the heat being generated in the power module, by heat exchange with the outside of the power module.

Moreover, to obtain further improved cooling efficiency, a cooling channel CC in which a refrigerant flows may be connected to the outside of the first substrate 110 or/and the second substrate 120.

Meanwhile, for example, each of the insulating layers may be made of ceramic, and each of the metal layers and the additional metal layer may be made of copper (Cu), for example. In the instant case, both of the first substrate 110 and the second substrate 120 may be realized by the active metal brazed (AMB) method or the direct bonded copper (DBC) method.

Furthermore, the first substrate 110 and the second substrate 120 may be expressed as an upper substrate and a lower substrate according to upper-lower arrangement relationship, and in the description below, it is assumed that the first substrate 110 is an upper substrate and the second substrate 120 is a lower substrate. However, the assumption is for convenience of description, and the arrangement relationship between the first substrate 110 and the second substrate 120 is not necessarily limited thereto.

The descriptions for the first substrate 110 and the second substrate 120 described above are only examples applicable to the exemplary embodiments of the present disclosure, and both the first substrate 110 and the second substrate 120 may have configuration, structure, material, etc. That are variously changed within a range in which the function for electrical connection inside the power module or heat transfer outward of the power module may be performed.

The semiconductor chip 200 may be electrically connected to the first substrate 110. The semiconductor chip 200 may be bonded to the first substrate 110 to be connected thereto, or may be connected to the first substrate 110 through the spacer 500 as shown in FIG. 1.

In the instant case, the semiconductor chip 200 may be electrically also connected to the second substrate 120, and according to the exemplary embodiment of the present disclosure, the semiconductor chip 200 and the second substrate 120 may not be electrically connected to each other. In other words, whether or not the semiconductor chip 200 and the second substrate 120 are connected to each other may be changed for various exemplary embodiments of the present disclosure.

Meanwhile, a cooling method of the power module may be divided into a double-surfaces cooling method and a single-surface cooling method.

First, when the semiconductor chip 200 is electrically connected to both the first substrate 110 and the second substrate 120, heat generated in an operation process of the semiconductor chip 200 is discharged toward both sides through the first substrate 110 and the second substrate 120, and therefore the cooling method of the power module may be referred to as the double-surfaces cooling method.

Otherwise, when the semiconductor chip 200 is electrically connected only to the first substrate 110 and is not connected to the second substrate 120, the heat generated in the semiconductor chip 200 is mainly discharged only through the first substrate 110, and therefore the cooling method may be referred to as the single-surface cooling method. In the instant case, it may be understood that the second substrate 120 is not provided to discharge the heat generated in the semiconductor chip 200 but is provided to embed the Hall element 300.

Meanwhile, the semiconductor chip 200 may be turned on/off according to a switching signal, and according to an on/off state, whether or not current flows between an upper portion and a lower portion of the semiconductor chip 200 is determined.

For example, the semiconductor chip 200 described above may be realized into a switching element such as an insulated gate bipolar transistor (IGBT) or a metal-oxide-semiconductor field-effect transistor (MOSFET), and silicon (Si) or silicon carbide (SiC) may be applied as material thereof.

The Hall element 300 is disposed between the first substrate 110 and the second substrate 120 and spaced from the sensing target portion 111 to face the sensing target portion 111, and the Hall element 300 is electrically connected to the outside of the power module thereby being used in sensing current of the sensing target portion 111.

The Hall element 300 is provided to detect current in the power module by the Hall effect which is when voltage is generated in response to change in magnetic field and in the instant case the voltage generated in the Hall element 300 may be referred to as Hall voltage.

The Hall voltage is formed perpendicular to current and magnetic field flowing in the Hall element 300. In the instant case, the magnetic field is generated by current flowing in the sensing target portion 111, and a direction of the magnetic field may be a third direction on the drawing based on the Hall element 300.

As the Hall element 300 is provided in the power module, by the Hall effect as described above, it is possible to detect the current in the sensing target portion 111 without in contact with the sensing target portion 111.

Comparing the Hall element of the present disclosure with when the Hall element is provided outside the power module, influence of other parts outside the power module to the magnetic field may be alleviated and the sensing performance may be improved.

Furthermore, comparing the Hall element of the present disclosure with when sensing current through an embedded shunt resistor, it is possible to alleviate influence of change in temperature due to heating of the resistor body to sensing, and current sensing may be performed only with relative small space. Accordingly, the volume of the power module may be reduced. Moreover, the internal space of an inverter in which the power module is mounted may be more spacious.

To perform the above current sensing, the Hall element 300 is disposed at the second substrate 120 and may be spaced from the first substrate 110, especially from the sensing target portion 111.

The Hall element 300 may be electrically connected to the first portion 121 of the second substrate 120 so that current for the current sensing through the Hall effect may be applied thereto, and the Hall element 300 may detect current of the sensing target portion 111 through the voltage generated according to the magnetic field due to the current flowing in the sensing target portion 111.

Meanwhile, the power module according to the exemplary embodiment of the present disclosure may include the signal pin 400 to achieve the electrical connection between the Hall element 300 and the outside of the power module. The signal pin 400 may be electrically connected to the Hall element 300, and the voltage generated in the Hall element may be applied to the signal pin 400.

At the present point, the signal pin 400 is provided to achieve the electrical connection between components, and may be formed of material such as metal, etc. having conductivity, and may include a form extending in the third direction thereof. However, the signal pin 400 may be realized by various methods unlike the above examples, and when an implemented form can perform electrical connection between the outside and inside of the power module regardless of material, form, name, etc., it may be included in the signal pin 400 of the present disclosure.

The signal pin 400 may be connected to an external control board, etc., and the control board, etc. may obtain current inside the power module, the current of the sensing target portion 111, through the voltage of the Hall element 300 transferred through the signal pin 400.

The Hall element 300 and the signal pin 400 may be connected to each other by various methods, and for example, referring to FIG. 1, the Hall element 300 may be connected to the signal pin 400 by wire bonding w1.

Otherwise, referring to FIG. 3, the Hall element 300 may be electrically connected to the signal pin 400 by bonding c with the signal pin 400, and a method of the connection with the signal pin 400 may be applied in combination.

Methods shown in FIGS. 1 and 3 correspond to a portion of various exemplary embodiments of the present disclosure, and other various connection methods may be applied to perform the electrical connection between the Hall element 300 and the signal pin 400.

Meanwhile, the Hall element 300 may be electrically connected to the outside of the power module through the first portion 121 of the second substrate 120. The first portion 121 is electrically connected to the outside of the power module and the Hall element 300 is connected to the first portion 121, so that the Hall element 300 may be electrically connected to the outside of the power module.

In the instant case, the first portion 121 may be connected to the outside of the power module through the signal pin 400, and the signal pin 400 may receive current generated in the Hall element 300 through the first portion 121, and may transfer the current to the outside of the power module.

In the instant case, the first portion 121 of the second substrate 120 may be electrically connected to the signal pin 400, and the Hall element 300 may be electrically connected to the signal pin 400 through the first portion 121.

Referring to FIG. 2 with respect to the relationship between the first portion 121 and the signal pin 400, the first portion 121 may be connected to the signal pin 400 by the wire bonding connection w2. Otherwise, referring to FIG. 3, the first portion 121 may be electrically connected to the signal pin 400 by the bonding c with the signal pin 400.

Meanwhile, referring to FIG. 1, FIG. 2, and FIG. 3 with respect to the connection between the Hall element 300 and the first portion 121, the Hall element 300 may be electrically connected to the first portion 121 by performing bonding c to the first portion 121 in a form of a bare die. Here, the form of a bare die may be implemented in a form in which the Hall element 300 is exposed without being protected by packaging through molding compounds or other packaging materials. In the instant case, the Hall element 300 may be packaged as part of the entire power module while being bonded to the first portion 121.

The bonding c of the Hall element 300 and the first portion 121 may be performed by soldering, sintering, or the like, and it is possible to use a method of bonding portions, where electrical connection is required, in a form of a solder ball, instead of bonding the entire areas in contact with each other. Otherwise, the bonding c of the Hall element 300 and the first portion 121 may be realized in various methods within a range in which the electrical connection is available.

Meanwhile, referring to FIG. 3, the signal pin 400 may include a signal pin 400-1, a signal pin 400-2, and a signal pin 400-3, and the signal pin 400-1 is directly connected to the Hall element 300 by bonding, the signal pin 400-2 is connected to the first portion 121 of the second substrate 120 by the wire bonding connection w2, and the signal pin 400-3 is directly connected to the first portion 121 of the second substrate 120 by bonding.

Meanwhile, referring to FIG. 4, unlike the above description, the Hall element 300 may be electrically connected to the first portion 121 through a connector 310.

To the present end, the connector 310 may be realized into a conductor, and for example, may include the same configuration as the metal layer of the first substrate 110 or the second substrate 120, but is not necessarily limited thereto.

In the instant case, the Hall element 300 may be electrically connected to the connector 310 by the wire bonding w′ to be connected to the first portion 121, or may be directly and electrically connected to the first portion 121. At the present point, a portion where the wire bonding w′ is connected to the Hall element 300 may be formed on a surface of the Hall element 300 opposite to a surface of the Hall element 300 facing the connector 310 or the first portion 121. However, the connection method between the Hall element 300 and the connector 310 is not limited to the above methods, and various methods may be used within a range in which the electrical connection is available.

Meanwhile, referring to FIG. 5, an insulating layer 320 may be inserted between the Hall element 300 and the connector 310. Also, the Hall element 300 and the connector 310 may be electrically connected to each other by the wire bonding w′ as described above.

Meanwhile, the first portion 121 may be divided into a plurality of portions 121-1, 121-2 in the third direction that crosses the first direction and the second direction, and the connector 310 may include a first connector 310-1 and a second connector 310-2 that are separated from each other and respectively connected to a corresponding one among the plurality of portions of the first portion.

In the instant case, the first connector 310-1 and the second connector 310-2 may correspond to different poles.

Meanwhile, the connector 310 may be electrically connected to the signal pin 400, and in the instant case, the Hall element 300 may be electrically connected to the signal pin 400 through the connector 310.

For example, the connector 310 and the signal pin 400 may be electrically connected to each other by wire bonding connection w3.

Meanwhile, the second substrate 120 may be electrically separated from the first portion 121, and may include a second portion 122 electrically connected to the semiconductor chip 200.

In the instant case, the second substrate 120 may be connected to the first substrate 110 through the semiconductor chip 200, and when the second substrate 120 is realized as described above, the power module may be cooled by the double-surfaces cooling method.

The first portion 121 and the second portion 122 may be insulated by being spaced from each other in the third direction that crosses the first direction and the second direction thereof. Moreover, an insulating body I may be inserted into the gap between the first portion 121 and the second portion 122.

Because the first portion 121 and the second portion 122 are electrically separated from each other, influence of high current in the power module in a process of sensing current through the Hall element 300 may be alleviated.

According to the various embodiments of the present disclosure described above, current sensing is performed through the Hall element provided in the power module, so that the influence due to changes in temperature and magnetic field in the current sensing process may be reduced.

Furthermore, it is possible to reduce the size and cost of the current sensor, and moreover, it is possible to reduce the size and cost of the power module, in which the current sensor is embedded, and an inverter.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

1-19. (canceled)

20. A power module including:
a first substrate including a sensing target portion in which a current path is formed;
a Hall element disposed to face the sensing target portion with an interval with the sensing target portion, and configured to generate voltage according to a magnetic field occurring due to a current flowing in the sensing target portion.

21. The power module of claim 20, further including:
a semiconductor chip electrically connected to the first substrate.

22. The power module of claim 20, further including:
a signal pin electrically connecting the Hall element to the outside of the power module.

23. The power module of claim 22, wherein the voltage generated in the Hall element is applied to the signal pin.

24. The power module of claim 22, wherein the Hall element is electrically connected to the signal pin by at least one selected from a group consisting of wire bonding connection and bonding with the signal pin.

25. The power module of claim 20, further including:
a second substrate disposed apart from the first substrate with the Hall element interposed between the first substrate and the second substrate.

26. The power module of claim 25, wherein the second substrate is connected to the Hall element to fix the Hall element at a position spaced from the sensing target portion.

27. The power module of claim 26, further including:
a spacer extended between the first substrate and the second substrate.

28. The power module of claim 27, wherein the spacer supports the first substrate and the second substrate to be spaced apart.

29. The power module of claim 28, wherein a first end of the spacer is connected to the first substrate and a second end of the spacer is connected to the second substrate.

30. The power module of claim 27, wherein the space is disposed on a side of the Hall element in a direction intersecting with the extended direction

31. The power module of claim 20, further including:
a spacer extended from the first substrate in a direction of the interval of the Hall element and the sensing target portion.

32. The power module of claim 31, wherein the spacer is disposed on a side of the Hall element is a direction intersecting with the extended direction.

33. The power module of claim 20, wherein a cooling channel is connected to the first substrate.
